(19) United States
(12) Patent Application Publication
(10) Pub. No.: US 2017/0222091 A1
(43) Pub. Date: Aug. 3, 2017

(54) NITRIDE SEMICONDUCTOR LIGHT EMITTING ELEMENT AND METHOD FOR MANUFACTURING THE SAME

(71) Applicant: USHIO DENKI KABUSHIKI KAISHA, Tokyo (JP)

(72) Inventors: Masashi TSUKIHARA, Himeji-shi, Hyogo (JP); Kohei MIYOSHI, Himeji-shi, Hyogo (JP); Toru SUGIYAMA, Himeji-shi, Hyogo (JP)

(73) Assignee: Ushio Denki Kabushiki Kaisha, Tokyo (JP)

(21) Appl. No.: 15/501,227

(22) PCT Filed: Jul. 31, 2015
(86) PCT No.: PCT/JP2015/071773

§ 371 Date: Feb. 2, 2017

(30) Foreign Application Priority Data
Aug. 8, 2014 (JP) 2014-163140

(51) Int. Cl. H01L 33/32; C01B 21/06; C23C 16/34; H01L 33/00

(52) U.S. Cl. CPC H01L 33/325; H01L 33/007; C01B 21/0602; C23C 16/34

(57) ABSTRACT

Provided is a nitride semiconductor light emitting element which has good luminous efficiency by suppressing deep-level emission and increasing the monochromaticity. A nitride semiconductor light emitting element according to the present invention comprises an active layer between an n-type nitride semiconductor layer and a p-type nitride semiconductor layer. The n-type nitride semiconductor layer contains Al_{X1}In_{X2}Ga_{X3}N (wherein 0<X1≦1, 0≦X2<1, 0≦X3<1, X1+X2+X3=1), and both the concentration of C contained therein and the concentration of O contained therein are less than or equal to 1×10¹⁷/cm³.

### TECHNICAL FIELD

The present invention relates to a nitride semiconductor light emitting element, and more particularly to a light emitting element with improved light emitting efficiency.

### BACKGROUND ART

Conventionally, light emitting elements using nitride semiconductor are widely used for blue light emitting diodes and the like. Recently, ultraviolet light emitting diodes (LED) having an emission wavelength in a shorter wavelength region, for example, at a 370 nm band region are under development.

However, when an ultraviolet light emitting device having an emission wavelength of less than or equal to 375 nm is produced, emission of the yellow visible light band (so called “deep emission”) is observed, and the phenomenon that the emission color of the device turns strongly whitish arises. This phenomenon leads yellow or white light emission although the light of the ultraviolet region is intended to be radiated, and leads the problem that the monochromaticity of the radiated light cannot be achieved due to the noise by the visible light component by the deep emission. Also, there is a problem that radiation of the light having a wavelength other than the required wavelength causes deterioration in the light emitting efficiency itself. The deep emission appears significantly in a light emitting device that emits short wavelength light of the ultraviolet region or the like.

While it has been thought that the deep emission is caused by emission in a defect or in an impurity level in the active layer, this thought is still unclear.

In Non-patent Document 1, some influence by C (carbon) on the deep emission is discussed based on the measurement of photoluminescence.

### PRIOR ART DOCUMENT

### Non-Patent Document

Non-patent Document 1: Mizuki et al., “Nuclear reaction analysis of C-doped GaN: Regarding the correlation between interstitial carbon and yellow luminescence”, March 2005, proceedings 31a-L-35 for the consociation lecture meeting associated with the 52nd conference of the Japan Society of Applied Physics.

### SUMMARY OF THE INVENTION

### Problems to be Solved by the Invention

The present inventors assumed that the deep emission could be attenuated by improving the quality of the active layer if the emission in a defect or in an impurity level in the active layer is a cause of the deep emission as described above. In other words, the present inventors assumed that the deep emission can be widely attenuated by minimizing the defect and the contained impurity (for example, C) in the active layer.

Based on this assumption, for different ultraviolet LED elements (51 to 55) having a major emission wavelength at a 370 mm band, the same current was applied, and for each element, the relationship between the emission output of the major emission wavelength of the element, and the ratio of the deep emission intensity to the light intensity of the major emission wavelength (hereinafter, referred to as “deep intensity ratio”) was measured. The measurement result is shown in FIG. 1.

It is assumed that the LED elements 54, 55 showing high light intensity of the major emission wavelength in the condition that the same current is applied, have an active layer of better quality containing less defect or impurities in comparison with the LED elements 51, 52.

Certainly, in the LED elements 52 to 55 assumed as having an active layer having a better quality than that of the LED element 51, the deep intensity ratio decreases. Based on only this point, it is assumed that the deep intensity ratio can be decreased by improving the quality of the active layer. That is, it can be concluded that the emission in a defect or in an impurity level in the active layer is a cause of the deep emission.

Since the emission output of the major emission wavelength increases greatly in the order of the LED elements 51, 52, 53, 54, and 55, it can be realized that the quality of the active layer improves in this order, however, the rate of decrease in the deep intensity ratio is significantly lower than the ratio of improvement in the emission output. In addition, comparing the LED elements 54 and 55, the deep intensity ratio little changes despite the appearance of adequate difference in the emission output.

Based on this experimental result, the present inventors assumed that deep emission is caused by other event different from the emission in a defect or in an impurity level in the active layer, and reached the idea that by investigating the cause, it is possible to decrease the deep intensity ratio.

It is an object of the present invention to provide a nitride semiconductor light emitting element having excellent light emitting efficiency by suppressing the deep emission and increasing the monochromaticity.

### Means for Solving the Problem

The present invention is a nitride semiconductor light emitting element having an active layer between an n-type nitride semiconductor layer and a p-type nitride semiconductor layer, and the n-type nitride semiconductor layer contains Al_{X1}In_{X2}Ga_{X3}N (0<X1≦1, 0≦X2<1, 0≦X3<1, X1+X2+X3=1), and both of a concentration of C and a concentration of O contained in the n-type nitride semiconductor layer are less than or equal to 1×10¹⁷/cm³.

As will be described later in Examples, through diligent efforts, the present inventors found that increased concentration of C contained in the n-type nitride semiconductor layer leads strong actualization of the deep emission from the light emitting element. Also, the present inventors found that by setting the concentration of C to be less than or equal to 1×10¹⁷/cm³, the emission output of the deep emission can be significantly reduced, relative to the emission output of the major emission wavelength. Further, the present inventors found that the emission output of the deep emission can be further reduced by reducing the concentration of O contained in the n-type nitride semiconductor layer while the concentration of C contained in the n-type nitride semiconductor layer is set to be less than or equal to 1×10¹⁷/cm³.

According to the diligent efforts made by the present inventors, the problem of the deep emission clearly appears in the nitride light emitting element for emitting light having a short wavelength such as ultraviolet light. For realizing an element that emits light having a short wavelength, the n-type nitride semiconductor layer is constituted of a material containing Al_{X1}In_{X2}Ga_{X3}N (0<X1≦1, 0≦X2<1, 0≦X3<1, X1+X2+X3=1). The present inventors assume that the deep emission arises by intake of C and O into an n-type nitride semiconductor layer containing Al during growth of the n-type nitride semiconductor layer containing Al. When the n-type nitride semiconductor layer was constituted of GaN and was not provided with a nitride layer containing Al so as to make the emission wavelength fall within a long wavelength range (for example, wavelength of greater than or equal to 420 nm), the intensity of the deep emission was very low. This would be ascribable to the difficulty in intake of C during growth of GaN.

In the above configuration, the nitride semiconductor light emitting element of the present invention may have a major emission wavelength of less than or equal to 375 nm. Since more or less deep emission arises even when the element is not an ultraviolet light emitting element, it is possible to realize the effect of suppressing the deep emission by setting the concentration of C and the concentration of O contained in the n-type nitride semiconductor layer to be less than or equal to 1×10¹⁷/cm³ for a light emitting element of which major emission wavelength exceeds 375 nm in the same manner.

In the above configuration, the concentration of O contained in the n-type nitride semiconductor layer may be less than or equal to 8×10¹⁶/cm³.

The nitride semiconductor light emitting element may be an ultraviolet light emitting element having a major emission wavelength of less than or equal to 375 nm, and an intensity ratio of an emission intensity of a yellow visible light wavelength to an emission intensity of the major emission wavelength may be less than or equal to 0.1%. The “intensity ratio” used herein means a ratio of a peak intensity of a yellow visible light wavelength of greater than or equal to 550 nm and less than or equal to 600 nm, to a peak intensity of the major emission wavelength.

As described above, by setting the concentration of C and the concentration of O contained in the n-type nitride semiconductor layer to be less than or equal to 1×10¹⁷/cm³, the intensity ratio of the emission intensity of the yellow visible light wavelength, to the emission intensity of the major emission wavelength is less than or equal to 0.1%, and the deep emission is suppressed to a non-problematic level.

### Effect of the Invention

According to the nitride semiconductor light emitting element of the present invention, since the deep emission is suppressed, a light emitting element having high monochromaticity and high light emitting efficiency is realized.

### BRIEF DESCRIPTION OF THE DRAWINGS

FIG. 1 is a graph showing the relationship between the emission output of the major emission wavelength and the ratio of the deep emission intensity to the light intensity of the major emission wavelength of each element when the same current is applied to different ultraviolet LED elements.

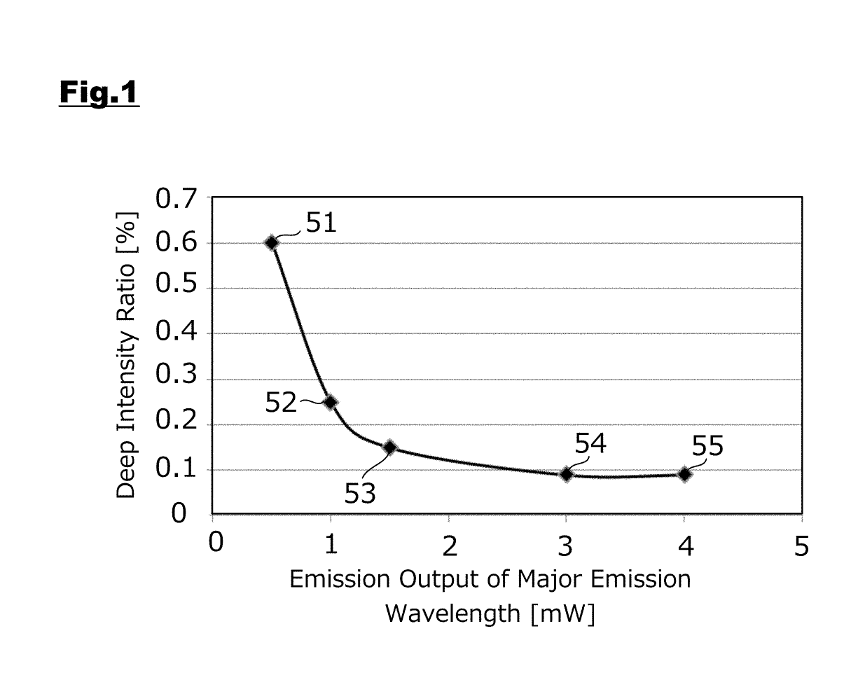

FIG. 2 is a schematic cross section view of a nitride semiconductor light emitting element.

FIG. 3 is a graph showing spectrum distribution of light when the same current is applied to three elements of Example 1, Example 2, and Comparative example 1.

FIG. 4 is a photo showing the light emitting mode when the same current is applied to three elements of Example 1, Example 2, and Comparative example 1.

FIG. 5 is a graph showing spectrum distributions of light when the same current is applied to four elements of Example 3, Example 4, Comparative example 2, and Comparative example 3.

FIG. 6 is another schematic cross section view showing the nitride semiconductor light emitting element.

### MODE FOR CARRYING OUT THE INVENTION

### [Structure]

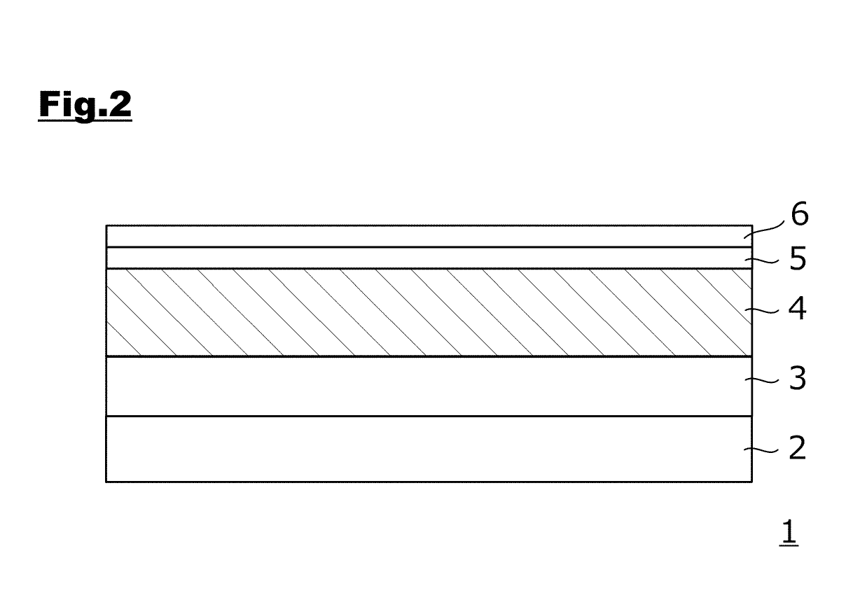

The structure of a nitride semiconductor light emitting element 1 according to the present invention will be described by referring to FIG. 2. FIG. 2 is a schematic cross section view of the nitride semiconductor light emitting element 1. Hereinafter, the nitride semiconductor light emitting element 1 is abbreviated as “LED element 1”.

In the present embodiment, description will be made for the LED element 1 embodied by an ultraviolet light emitting element having a major emission wavelength of a 370 nm band, however, the emission wavelength is not limited to this value.

The LED element 1 is formed by laminating a substrate 2, an undoped layer 3, an n-type nitride semiconductor layer 4, an active layer 5, and a p-type nitride semiconductor layer 6 in this order from below.

### (Substrate 2)

The substrate 2 is constituted of a sapphire substrate. Here, instead of sapphire, the substrate 2 may be constituted of Si, SiC, AlN, AlGaN, GaN, YAG, or the like.

### (Undoped Layer 3)

The undoped layer 3 is formed of GaN. More specifically, the undoped layer 3 is formed of a low-temperature buffer layer made of GaN and an underlayer made of GaN on top thereof.

### (N-Type Nitride Semiconductor Layer 4)

The n-type nitride semiconductor layer 4 is constituted of Al_{X1}In_{X2}Ga_{X3}N (0<X1≦1, 0≦X2<1, 0≦X3<1, X1+X2+X3=1) formed so that a concentration of C and a concentration of O contained as impurities are less than or equal to 1×10¹⁷/cm³. The method for reducing the contained concentration of C and concentration of O will be described later.

### (Active Layer 5)

The active layer 5 is made up of, for example, a light emitting layer of InGaN and a barrier layer of AlGaN that are plurally repeated. These layers may be undoped, or may be doped into p-type or n-type.

### (P-Type Nitride Semiconductor Layer 6)

The p-type nitride semiconductor layer 6 is constituted of Al_{Y1}In_{Y2}Ga_{Y3}N (0<Y1≦1, 0≦Y2<1, 0≦Y3<1, Y1+Y2+Y3=1). Unlike the n-type nitride semiconductor layer 4, the concentration of C and the concentration of O contained as impurities may be larger than 1×10¹⁷/cm³ in the p-type nitride semiconductor layer 6. Also this point will be described later.

Although not illustrated in FIG. 2, the LED element 1 may have a high concentration p-type GaN layer for contact on top of the p-type nitride semiconductor layer 6. Also an n-side electrode may be provided on top of the n-type nitride semiconductor layer 4 exposed by etching, and a p-side electrode may be provided on top of the high concentration p-type GaN layer.

The n-type nitride semiconductor layer 4 may be constituted only of an Al_{X1}In_{X2}Ga_{X3}N layer, or may contain an Al_{X1}In_{X2}Ga_{X3}N layer and a GaN layer. The Al_{X1}In_{X2}Ga_{X3}N layer may be made up of any of an MN layer, an AlGaN layer, and an AlInGaN layer, or may be a laminate of multiple layers of these. When the n-type nitride semiconductor layer 4 is constituted of an AlInGaN layer, the composition ratio of In may be extremely low (for example, less than 1%). The same applies to the p-type nitride semiconductor layer 6.

### [Manufacturing Process]

Next, the manufacturing process of the LED element 1 shown in FIG. 2 will be described. This manufacturing process is merely one example, and the flow rate of gas, the temperature within the furnace, the pressure within the furnace and the like may be appropriately adjusted.

First, the undoped layer 3 is formed on top of the substrate 2. This is realized, for example, by the following method.

### (Preparation of Substrate 2)

A sapphire substrate is prepared as the substrate 2, and the c-plane sapphire substrate is cleaned. More specifically, this cleaning is carried out, for example, by placing the c-plane sapphire substrate in a processing furnace of an MOCVD (Metal Organic Chemical Vapor Deposition: organic metal chemical gas-phase vapor deposition) apparatus and raising the temperature within the furnace to be, for example, 1150° C. while allowing a hydrogen gas to flow at a flow rate of 10 slm in the processing furnace.

### (Forming Undoped Layer 3)

Next, a low-temperature buffer layer made of GaN is formed on the surface of c-plane sapphire substrate, and further an underlayer made of GaN is formed on top thereof. The low-temperature buffer layer and the underlayer correspond to the undoped layer 3.

A more specific method of forming the undoped layer 3 is, for example, as follows. First, the pressure within the furnace of the MOCVD apparatus is set to be 100 kPa, and the temperature within the furnace is set to be 480° C. Then, trimethylgallium (TMG) having a flow rate of 50 μmol/min and ammonia having a flow rate of 223000 μmol/min are supplied as source material gases for 68 seconds into the processing furnace while allowing a nitrogen gas and a hydrogen gas each having a flow rate of 5 slm to flow as carrier gases in the processing furnace. By this process, the low-temperature buffer layer made of GaN and having a thickness of 20 nm is formed on the surface of c-plane sapphire substrate.

Next, the temperature within the furnace of the MOCVD apparatus is raised to 1150° C. Then, TMG having a flow rate of 100 μmol/min and ammonia having a flow rate of 223000 μmol/min are supplied as source material gases for 30 minutes into the processing furnace while allowing a nitrogen gas having a flow rate of 20 slm and a hydrogen gas having a flow rate of 15 slm to flow as carrier gases in the processing furnace. By this process, the underlayer made of GaN and having a thickness of 1.7 μm is formed on the surface of the low-temperature buffer layer.

(Formation of n-Type Nitride Semiconductor Layer 4)

Next, the n-type nitride semiconductor layer 4 having a composition of Al_{X1}In_{X2}Ga_{X3}N is formed on top of the undoped layer 3.

A more concrete method for forming the n-type nitride semiconductor layer 4 is, for example, as follows. First, in the condition that the temperature within the furnace is kept at 1150° C., the pressure within the furnace of the MOCVD apparatus is set to be 30 kPa. Then while a nitrogen gas having a flow rate of 20 slm and a hydrogen gas having a flow rate of 15 slm are flown as carrier gases in the processing furnace, TMG, trimethylaluminum (TMA), ammonia and tetraethylsilane for doping with an n-type impurity are supplied as source material gases into the processing furnace for 30 minutes. As a result, the n-type nitride semiconductor layer 4 having a composition of, for example, Al_{0.06}Ga_{0.94}N and a thickness of 1.7 μm is formed on top of the undoped layer 3.

By setting the flow rate ratio between ammonia which is Group V, and TMG and TMA which are Group III (V/III ratio) to be larger than or equal to 2000, it is possible to set the concentration of C contained in the n-type nitride semiconductor layer 4 to be less than or equal to 1×10¹⁷/cm³. The concentration of O contained in the n-type nitride semiconductor layer 4 at this time can also be set to be less than or equal to 1×10¹⁷/cm³. When the growth speed changes with the change in the flow rate of ammonium, the time is adjusted so that a desired film thickness is obtained, and thus an element is produced.

For example, by using ammonia having a flow rate of 223000 μmol/min, TMG having a flow rate of 100 μmol/min, and TMA having a flow rate of 7 μmol/min as source materials, the V/III ratio can be set to be about 2000. Although tetraethylsilane also contains C atoms, the flow rate thereof is, for example, about 0.025 μmol/min, and thus the influence on the concentration of C contained in the n-type nitride semiconductor layer 4 is neglectable in comparison with TMG and TMA.

When the V/III ratio was 1000, the concentration of C contained in the generated n-type nitride semiconductor layer 4 was 5×10¹⁷/cm³, and the concentration of O contained in the generated n-type nitride semiconductor layer 4 was 7×10¹⁶/cm³ (later-described Comparative example 1). When the V/III ratio was 2000, the concentration of C was 1×10¹⁷/cm³, and the concentration of O was 5×10¹⁶/cm³ (later-described Example 2). When the V/III ratio was 4000, the concentration of C was 5×10¹⁶/cm³, and the concentration of O was 4×10¹⁶/cm³ (later-described Example 1). The concentration of C contained in the generated n-type nitride semiconductor layer 4 was measured by SIMS (secondary ion mass spectrometry).

TMG and TMA which are source material gases contain a C atom as a constituting molecule. Meanwhile, ammonia does not contain a C atom. Therefore, by increasing the V/III ratio, it is possible to reduce the concentration of C contained in the formed n-type nitride semiconductor layer 4.

It is also possible to reduce the concentration of C contained in the n-type nitride semiconductor layer 4 by increasing the growth pressure besides increasing the V/III ratio. This would be because the same effect as obtained by increasing the V/III ratio can be obtained as a result of formation of an ammonia rich environment in the furnace due to extension of the time during which ammonia resides in the MOCVD apparatus by increasing the growth pressure. In this case, the growth pressure is preferably greater than or equal to 30 kPa and less than or equal to 100 kPa, and more preferably greater than or equal to 50 kPa and less than or equal to 100 kPa.

Here, silicon (Si), germanium (Ge), sulfur (S), selenium (Se), tin (Sn), tellurium (Te), and others may be used as the n-type impurity contained in the n-type nitride semiconductor layer 4. Among these, silicon (Si) is especially preferable.

By reducing the concentration of C contained in the n-type nitride semiconductor layer 4 by increasing the V/III ratio of the source material gas, or by increasing the growth pressure as is conducted in this step, it is sometimes possible to reduce the concentration of O contained in the n-type nitride semiconductor layer 4.

### (Formation of Active Layer 5)

Next, the active layer 5 is formed on top of the n-type nitride semiconductor layer 4.

Concretely, first, the pressure within the furnace of the MOCVD apparatus is set to be 100 kPa, and the temperature within the furnace is set to be 830° C. Then the step of supplying the interior of the processing furnace with TMG having a flow rate of 10 μmol/min, trimethylindium (TMI) having a flow rate of 12 μmol/min and ammonia having a flow rate of 300000 μmol/min as source material gases for 48 seconds while flowing a nitrogen gas having a flow rate of 15 slm and a hydrogen gas having a flow rate of 1 slm as carrier gases in the processing furnace is conducted. Then the step of supplying the interior of the processing furnace with TMG having a flow rate of 10 μmol/min, TMA having a flow rate of 1.6 μmol/min, tetraethylsilane having a flow rate of 0.002 μmol/min, and ammonia having a flow rate of 300000 μmol/min as source material gases for 120 seconds is conducted. Thereafter, by repeating these steps, the active layer 5 in which a light-emitting layer constituted of InGaN and having a thickness of 2 nm, and a barrier layer constituted of n-type AlGaN and having a thickness of 7 nm are repeated 15 cycles is formed on the surface of the n-type nitride semiconductor layer 4.

(Formation of p-Type Nitride Semiconductor Layer 6)

Next, the p-type nitride semiconductor layer 6 constituted of Al_{Y1}In_{Y2}Ga_{Y3}N is formed on top of the active layer 5.

Concretely, the pressure within the furnace of the MOCVD apparatus is maintained to be 100 kPa, and the temperature within the furnace is raised to 1025° C. while a nitrogen gas having a flow rate of 15 slm and a hydrogen gas having a flow rate of 25 slm are allowed to flow as carrier gases in the processing furnace. Thereafter, TMG having a flow rate of 35 μmol/min, TMA having a flow rate of 20 μmol/min, ammonia having a flow rate of 250000 μmol/min, and biscyclopentadienyl magnesium (Cp₂Mg) having a flow rate of 0.1 μmol/min for doping with a p-type impurity are supplied as source material gases into the processing furnace for 60 seconds. By this process, a hole supply layer having a composition of Al_{0.3}Ga_{0.7}N and having a thickness of 20 nm is formed on the surface of the active layer 5. Thereafter, by changing the flow rate of TMG to 9 μmol/min and supplying the source material gases for 360 seconds, a hole supply layer having a composition of Al_{0.13}Ga_{0.87}N and having a thickness of 120 nm is formed. These hole supply layers constitute the p-type nitride semiconductor layer 6.

Here, in the process of forming the p-type nitride semiconductor layer 6, since the film is grown at a temperature lower than that in the process of forming the n-type nitride semiconductor layer 4, the interior of the furnace has an Group III-rich environment compared with that at the time of forming the n-type nitride semiconductor layer 4. Therefore, the concentration of C contained in the p-type nitride semiconductor layer 6 can be higher than that of the n-type nitride semiconductor layer 4. However, as will be described later, even when the concentration of C contained in the p-type nitride semiconductor layer 6 was as high as about 1×10¹⁹/cm³, for example, it was possible to obtain the effect of attenuating the deep emission by setting the concentration of C contained in the n-type nitride semiconductor layer 4 to be less than or equal to 1×10¹⁷/cm³.

As the p-type impurity, magnesium (Mg), beryllium (Be), zinc (Zn), carbon (C) or the like can be used.

### (Subsequent Step)

After formation of the p-type nitride semiconductor layer 6, supply of the TMA is stopped, and the flow rate of biscyclopentadienyl is changed to 0.2 μmol/min and the source material gas is supplied for 20 seconds. By this process, a high concentration p-type GaN layer constituted of p-type GaN and having a thickness of 5 nm is formed.

The subsequent steps are as follows.

For realizing the semiconductor light emitting element 1 having a so-called “lateral structure” in which an n-side electrode and a p-type electrode are arranged on the same plane side of the substrate 2, the upper face of a part of the n-type nitride semiconductor layer 4 is exposed by ICP etching, and on top of the exposed n-type nitride semiconductor layer 4, an n-side electrode is formed, and on top of the p-type nitride semiconductor layer 6, a p-side electrode is formed. Then the elements are separated from each other, for example, by a laser dicing apparatus, and wire bonding is conducted on the electrodes.

On the other hand, in the case of producing the semiconductor light emitting element 1 having a so-called “vertical structure” in which an n-side electrode is arranged on one plane of the substrate, and a p-side electrode is arranged on the other plane, the following procedure is employed. First, on top of the p-type nitride semiconductor layer 6, a metal electrode (reflection electrode) which is to become a p-side electrode, a solder diffusion preventive layer, and a solder layer are formed. Then after bonding a support substrate (for example, CuW substrate) constituted of a conductor or a semiconductor via the solder layer, the resultant laminate is turned upside down, and the substrate 2 is peeled off by a method such as laser irradiation. Thereafter, the n-side electrode is formed on top of the n-type nitride semiconductor layer 4. Then, separation of elements and wire bonding are conducted in the same manner as in the lateral structure.

### EXAMPLES

Hereinafter, the present invention will be described by referring to examples.

### (Verification 1)

Three elements of Example 1, Example 2, and Comparative example 1 were formed in the same conditions except that only the V/III ratio of the source material gas at the time of forming the n-type nitride semiconductor layer 4 was changed in the aforementioned process. Every element is an ultraviolet light emitting element having a major emission wavelength of 370 nm.

### Example 1

The element was formed while the V/III ratio was set to be 4000. The concentration of C contained in the n-type nitride semiconductor layer 4 was 5×10¹⁶/cm³, and the concentration of O contained in the n-type nitride semiconductor layer 4 was 4×10¹⁶/cm³.

### Example 2

The element was formed while the V/III ratio was set to be 2000. The concentration of C contained in the n-type nitride semiconductor layer 4 was 1×10¹⁷/cm³, and the concentration of O contained in the n-type nitride semiconductor layer 4 was 5×10¹⁶/cm³.

### Comparative Example 1

The element was formed while the V/III ratio was set to be 1000. The concentration of C contained in the n-type nitride semiconductor layer 4 was 5×10¹⁷/cm³, and the concentration of O contained in the n-type nitride semiconductor layer 4 was 7×10¹⁶/cm³.

In every element, the V/III ratio of the source material gas at the time of forming the p-type nitride semiconductor layer 6 was 6000, and the concentration of C contained in the p-type nitride semiconductor layer 6 was 1×10¹⁷/cm³.

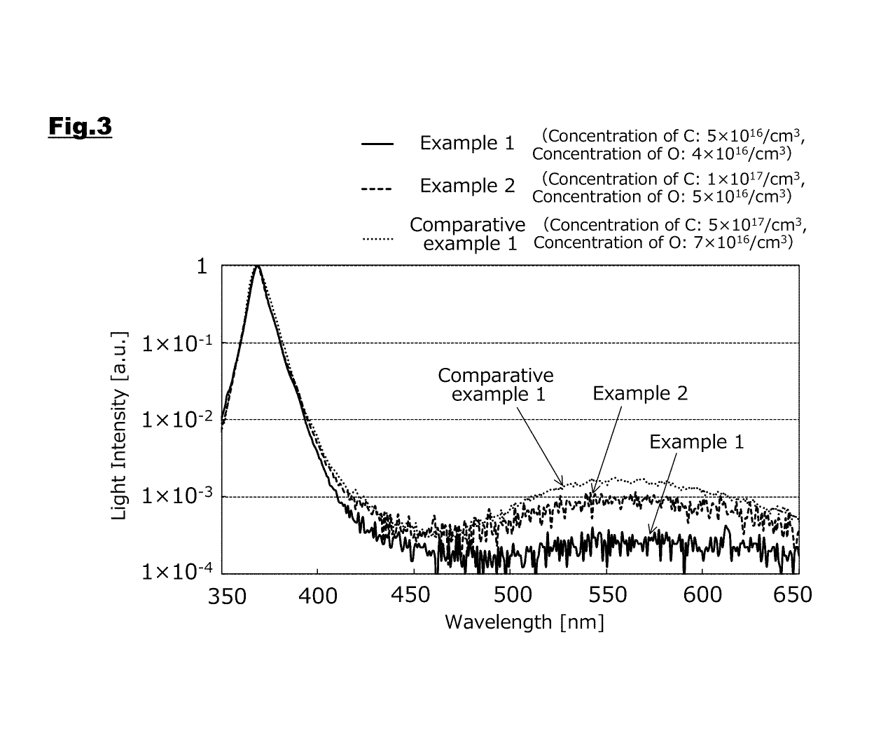

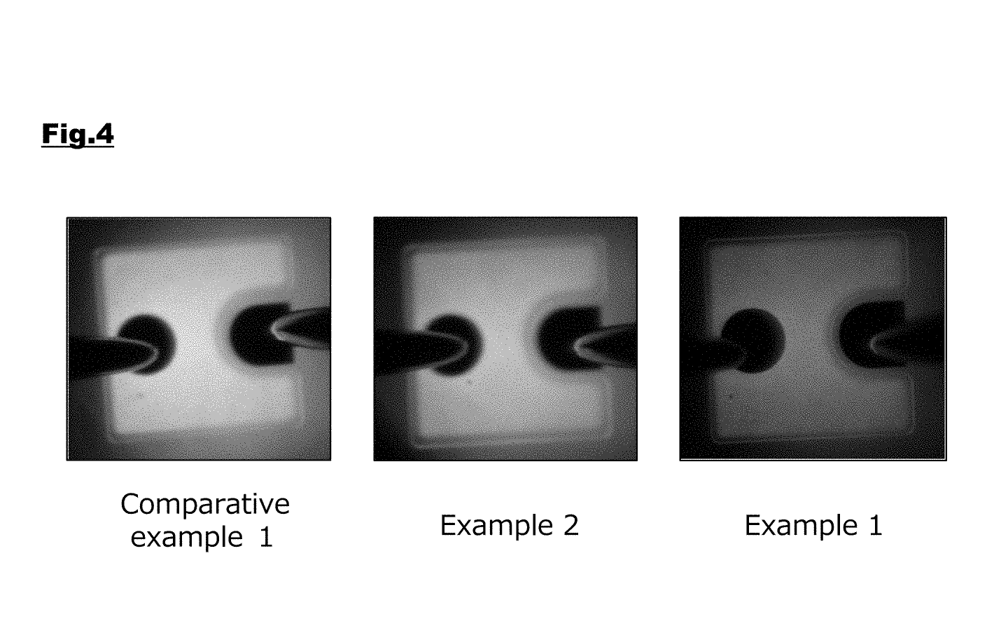

FIG. 3 is a graph showing spectrum distributions of light obtained when the same voltage is applied to the three elements of Example 1, Example 2, and Comparative example 1. The horizontal axis represents an emission wavelength, and the vertical axis represents a light intensity. FIG. 4 shows photographs showing the light emitting condition of each element.

As shown in FIG. 3, in Comparative example 1, the ratio (deep intensity ratio) of the intensity of the emission wavelength of the band of 550 nm to 600 nm including the yellow visible light wavelength range (deep emission), to the emission intensity of 370 nm band is about 0.3, which exceeds 0.1%. In this case, while dark violet light would be emitted under the influence of the violet visible light corresponding to the flared part of the peak wavelength by emission of the ultraviolet light under normal circumstances, considerably whitish lighting is observed under the influence of the deep emission as can be seen in FIG. 4. As a result of mixture of the violetish light and the yellowish light, the emitting light is whitish. According to FIG. 3, the deep intensity ratio of Example 1 is about 0.03%, and the deep intensity ratio of Example 2 is about 0.09%.

In contrast to this, in Example 1 and Example 2, the deep intensity ratio is suppressed to less than or equal to 0.1%, and also in the photographs of FIG. 4, the whitishness is reduced in the color of the light emitted from the elements, and dark color is observed. Comparison among Comparative example 1, Example 1, and Example 2 reveals that the effect of decreasing the deep intensity ratio is obtained as the concentration of C contained in the n-type nitride semiconductor layer 4 is reduced.

Also the measurement was conducted in the same manner as in Example 2 by setting the V/III ratio of the source material gas at the time of forming the p-type nitride semiconductor layer 6 to be 1000, and raising the concentration of C contained in the p-type nitride semiconductor layer 6 to 1×10¹⁹/cm³ in the condition that the concentration of C contained in the n-type nitride semiconductor layer 4 was 1×10¹⁷/cm³, however, no significant difference from Example 2 was observed. This also indicates that the concentration of C contained in the n-type nitride semiconductor layer 4 influences on the deep emission.

That is, it can be found that the deep emission is derived from the impurity level produced by C contained in the n-type nitride semiconductor layer 4 rather than in the active layer 5. Therefore, it is possible to suppress the deep emission by making the concentration of C contained in the n-type nitride semiconductor layer 4 as small as possible.

When Mg is doped as an impurity of the p-type nitride semiconductor layer 6, it is expected that emission derived from the level at C is suppressed by the level produced by Mg. Therefore, the impurity concentration of C contained in the p-type nitride semiconductor layer 6 would not influence on the deep emission at least if it is less than or equal to the doping amount of Mg. Since the doping concentration of Mg is about 1 to 2×10¹⁹/cm³, a concentration of C contained in the p-type nitride semiconductor layer 6 around 1×10¹⁹/cm³ does not influence on the deep emission. However, when the n-type nitride semiconductor layer 4 contains C in a comparable concentration of C, high deep emission occurs as is already described.

Since the active layer 5 is also constituted of an n-polar nitride semiconductor, a lower concentration of C contained in the active layer 5 is preferred. However, since the active layer 5 has a very small thickness compared with the n-type nitride semiconductor layer 4, the absolute amount of C contained therein is very small compared with the n-type nitride semiconductor layer 4. Therefore, actually, contribution to the deep emission is not as large as the concentration of C contained in the n-type nitride semiconductor layer 4.

### (Verification 2)

Four elements of Example 3, Example 4, Comparative example 2, and Comparative example 3 were formed while the V/III ratio of the source material gas at the time of forming the n-type nitride semiconductor layer 4 was changed in the above-described process. Every element is an ultraviolet light emitting element having a major emission wavelength of 370 nm band.

### Example 3

The element was formed while the V/III ratio was set to be 5000. The concentration of C contained in the n-type nitride semiconductor layer 4 was 3×10¹⁶/cm³, and the concentration of O contained in the n-type nitride semiconductor layer 4 was 8×10¹⁶/cm³.

### Example 4

The element was formed while the V/III ratio was set to be 5000. The concentration of C contained in the n-type nitride semiconductor layer 4 was 3×10¹⁶/cm³, and the concentration of O contained in the n-type nitride semiconductor layer 4 was 3×10¹⁶/cm³.

### Comparative Example 2

The element was formed while the V/III ratio was set to be 5000. The concentration of C contained in the n-type nitride semiconductor layer 4 was 3×10¹⁶/cm³, and the concentration of O contained in the n-type nitride semiconductor layer 4 was 2×10¹⁷/cm³.

### Comparative Example 3

The element was formed while the V/III ratio was set to be 1300. The concentration of C contained in the n-type nitride semiconductor layer 4 was 2×10¹⁷/cm³, and the concentration of O contained in the n-type nitride semiconductor layer 4 was 5×10¹⁶/cm³.

In every element, the V/III ratio of the source material gas at the time of forming the p-type nitride semiconductor layer 6 was 6000, and the concentration of C contained in the p-type nitride semiconductor layer 6 was 1×10¹⁷/cm³.

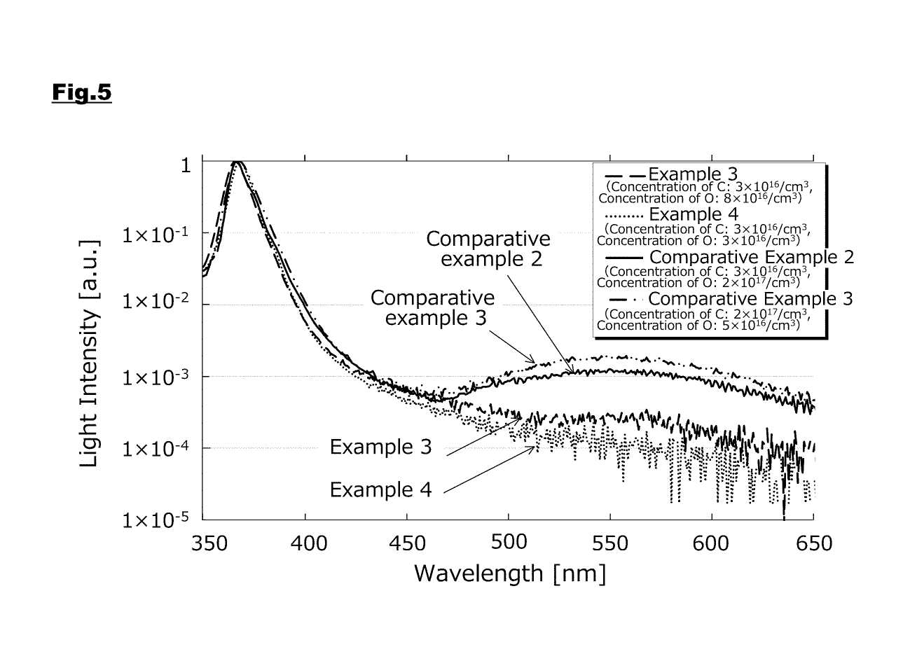

FIG. 5 is a graph showing spectrum distributions of light obtained when the same voltage is applied to the four elements of Example 3, Example 4, Comparative example 2, and Comparative example 3. The horizontal axis represents an emission wavelength, and the vertical axis represents a light intensity.

As shown in FIG. 5, in Comparative example 2, the ratio (deep intensity ratio) of the intensity of the emission wavelength of the band of 550 nm to 600 nm including the yellow visible light wavelength range (deep emission), to the emission intensity of 370 nm band is about 0.12%. In Comparative example 3, the deep intensity ratio is about 0.19%. In contrast to this, the deep intensity ratio of Example 3 is about 0.03%, and the deep intensity ratio of Example 4 is about 0.02%.

In each element of Comparative example 2, Example 3, and Example 4, the concentration of C contained in the n-type nitride semiconductor layer 4 is 3×10¹⁶/cm³ which is lower than 1×10¹⁷/cm³. These elements can realize a low deep intensity ratio in comparison with the elements of Comparative example 1 and Comparative example 3 in which the concentration of C contained in the n-type nitride semiconductor layer 4 is higher than 1×10¹⁷/cm³. This also suggests that setting the concentration of C contained in the n-type nitride semiconductor layer 4 to be less than or equal to 1×10¹⁷/cm³, as described above is effective for decreasing the deep intensity ratio.

On the other hand, when the respective elements of Comparative example 2, Example 3, and Example 4 are compared, the element of Comparative example 2 shows a deep intensity ratio slightly higher than 0.1%, and the elements of Example 3 and Example 4 show a deep intensity ratio of lower than 0.1%. This result suggests that reducing the concentration of O contained in the n-type nitride semiconductor layer 4 in addition to setting the concentration of C contained in the n-type nitride semiconductor layer 4 to be lower than or equal to 1×10¹⁷/cm³ is effective for further decreasing the deep intensity ratio.

In each element of Examples 1 to 4 where the deep intensity ratio is less than 0.1%, the concentration of O contained in the n-type nitride semiconductor layer 4 is 4×10¹⁶/cm³ in Example 1, 5×10¹⁶/cm³ in Example 2, 8×10¹⁶/cm³ in Example 3, and 3×10¹⁶/cm³ in Example 4. And the concentration of O contained in the n-type nitride semiconductor layer 4 in the element of Comparative example 2 where the deep intensity ratio is slightly higher than 0.1% is 2×10¹⁷/cm³.

In the verification 1, when elements of Example 1, Example 2, and Comparative example 1 were produced in the same conditions except that only the V/III ratio of the source material gas at the time of forming the n-type nitride semiconductor layer 4 was changed, the concentration of O contained in the n-type nitride semiconductor layer 4 increased with the concentration of C contained therein, and the concentration of O contained in the n-type nitride semiconductor layer 4 showed a value lower than the concentration of C contained therein. This suggests that C is more likely to be taken into the n-type nitride semiconductor layer 4 than O, and O can be taken in association with C.

Further, comparing the element of Comparative example 2 having the concentration of C contained in the n-type nitride semiconductor layer 4 of 3×10¹⁶/cm³, and the concentration of O contained therein of 2×10¹⁷/cm³, and the element of Comparative example 1 having the concentration of C contained in the n-type nitride semiconductor layer 4 of 5×10¹⁷/cm³, and the concentration of O contained therein of 7×10¹⁶/cm³, the element of the Comparative example 1 shows a very high deep intensity ratio compared with the element of Comparative example 2. In light of this, it would be possible to set the deep intensity ratio to be less than or equal to 0.1% by setting the concentration of C contained in n-type nitride semiconductor layer 4 to be less than or equal to 1×10¹⁷/cm³, and setting the concentration of O contained in the same layer to be less than or equal to 1×10¹⁷/cm³ which is comparable to the condition of the concentration of C contained therein. Further, it is more preferred to set the concentration of C contained in the n-type nitride semiconductor layer 4 to be less than or equal to 1×10¹⁷/cm³, and to set the concentration of O contained therein to be less than or equal to 8×10¹⁶/cm³.

### Another Embodiment

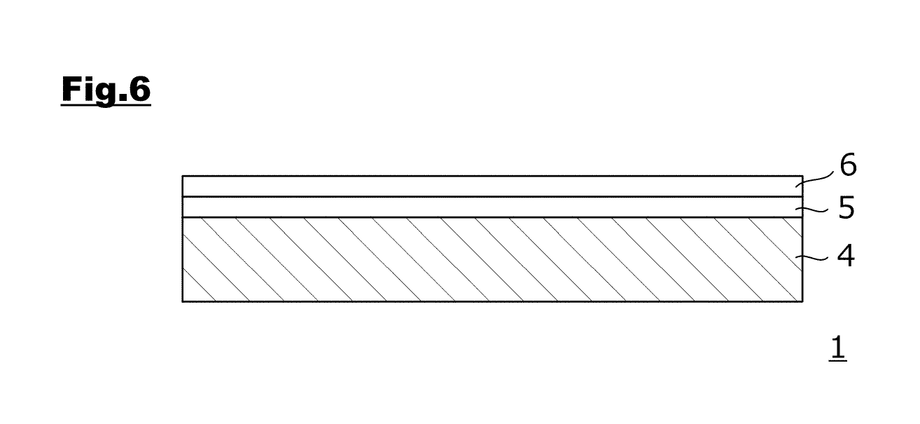

In the above description, the LED element 1 shown in FIG. 2 has the substrate 2 and the undoped layer 3; however, the configuration in which these are peeled off (see FIG. 6) may be employed. Also in this case, the effects similar to those described above by referring to FIGS. 3 to 5 were obtained.

### DESCRIPTION OF REFERENCE SIGNS

1: nitride semiconductor light emitting element
2: substrate
3: undoped layer
4: n-type nitride semiconductor layer
5: active layer
6: p-type nitride semiconductor layer
51, 52, 53, 54, 55: LED element(s)

1. A nitride semiconductor light emitting element having an active layer between an n-type nitride semiconductor layer and a p-type nitride semiconductor layer, wherein
the n-type nitride semiconductor layer contains Al_{X1}In_{X2}Ga_{X3}N (0<X1≦1, 0≦X2<1, 0≦X3<1, X1+X2+X3=1), and both of a concentration of C and a concentration of O contained in the n-type nitride semiconductor layer are less than or equal to 1×10¹⁷/cm³, and
a concentration of a p-type impurity contained in the p-type nitride semiconductor layer is higher than the concentration of C contained in the n-type nitride semiconductor layer.

2. The nitride semiconductor light emitting element according to claim 1, wherein the concentration of O contained in the n-type nitride semiconductor layer is less than or equal to 8×10¹⁶/cm³.

3. The nitride semiconductor light emitting element according to claim 1, which is an ultraviolet light emitting element having a major emission wavelength of less than or equal to 375 nm.

4. The nitride semiconductor light emitting element according to claim 3, wherein an intensity ratio of an emission intensity of a yellow visible light wavelength to an emission intensity of the major emission wavelength is less than or equal to 0.1%.

5. The nitride semiconductor light emitting element according to claim 1, comprising a sapphire substrate, wherein the n-type nitride semiconductor layer, the p-type nitride semiconductor layer, and the active layer are formed on a C plane of the sapphire substrate.

6. A method for producing a nitride semiconductor light emitting element, comprising the steps of:
(a) preparing a sapphire substrate, and
(b) forming an n-type nitride semiconductor layer, an active layer, and a p-type nitride semiconductor layer on a C plane of the sapphire substrate,
wherein in the step (b), the n-type nitride semiconductor layer contains Al_{X1}In_{X2}Ga_{X3}N (0<X1≦1, 0≦X2<1, 0≦X3<1, X1+X2+X3=1), and both of a concentration of C and a concentration of O contained in the n-type nitride semiconductor layer are less than or equal to 1×10¹⁷/cm³, and
a concentration of a p-type impurity contained in the p-type nitride semiconductor layer is higher than the concentration of C contained in the n-type nitride semiconductor layer.

7. The method for producing a nitride semiconductor light emitting element according to claim 6, wherein in the step (b), the n-type nitride semiconductor layer is allowed to grow in a condition that a V/III ratio which is a flow rate ratio between a source material of Group V and a source material of Group III is set to be more than or equal to 2000.

8. The nitride semiconductor light emitting element according to claim 2, which is an ultraviolet light emitting element having a major emission wavelength of less than or equal to 375 nm.

9. The nitride semiconductor light emitting element according to claim 8, wherein an intensity ratio of an emission intensity of a yellow visible light wavelength to an emission intensity of the major emission wavelength is less than or equal to 0.1%.

10. The nitride semiconductor light emitting element according to claim 2, comprising a sapphire substrate, wherein the n-type nitride semiconductor layer, the p-type nitride semiconductor layer, and the active layer are formed on a C plane of the sapphire substrate.

11. The nitride semiconductor light emitting element according to claim 3, comprising a sapphire substrate, wherein the n-type nitride semiconductor layer, the p-type nitride semiconductor layer, and the active layer are formed on a C plane of the sapphire substrate.

12. The nitride semiconductor light emitting element according to claim 4, comprising a sapphire substrate, wherein the n-type nitride semiconductor layer, the p-type nitride semiconductor layer, and the active layer are formed on a C plane of the sapphire substrate.

13. The nitride semiconductor light emitting element according to claim 8, comprising a sapphire substrate, wherein the n-type nitride semiconductor layer, the p-type nitride semiconductor layer, and the active layer are formed on a C plane of the sapphire substrate.

14. The nitride semiconductor light emitting element according to claim 9, comprising a sapphire substrate, wherein the n-type nitride semiconductor layer, the p-type nitride semiconductor layer, and the active layer are formed on a C plane of the sapphire substrate.
